(19) United States
(12) Patent Application Publication
(10) Pub. No.: US 2026/0354224 A1
(43) Pub. Date: Nov. 5, 2026

(54) ELECTRONIC DEVICE

(71) Applicant: Advanced Semiconductor Engineering, Inc., Kaohsiung (TW)

(72) Inventors: Kuofeng HUANG, Kaohsiung (TW); Che-Ting LI, Kaohsiung (TW); Hung-I LIN, Kaohsiung (TW); Chi Hao CHIANG, Kaohsiung (TW); Hsin-Chin CHANG, Kaohsiung (TW)

(73) Assignee: Advanced Semiconductor Engineering, Inc., Kaohsiung (TW)

(21) Appl. No.: 19/195,701

(22) Filed: Apr. 30, 2025

(51) Int. Cl. H10W 70/60; H10D 1/68; H10W 74/10; H10W 90/00

(52) U.S. Cl. CPC H10W 70/614; H10W 70/611; H10W 74/124; H10W 90/00; H10W 90/401; H10D 1/68

(57) ABSTRACT

The present disclosure provides an electronic device. The electronic device includes a standoff structure, a first component, a second component, and an interposer. The standoff structure defines a space. The first component is disposed within the space. The second component is disposed over the standoff structure. The interposer is disposed between the second component and the standoff structure.

### BACKGROUND

### 1. Technical Field

The present disclosure relates to an electronic device.

### 2. Description of the Related Art

Power management integrated circuits (PMICs) leverage System-in-Package (SiP) technology, including double side molding, 2.5D/3D IC, etc., to integrate multiple chips or components into a package. However, to provide different types of power control and to adapt to demands of high-speed data communication, bulky passive components may be needed. As a result, the package size may be increased, and thus the layout design flexibility may be diminished.

### SUMMARY

In some arrangements, an electronic device includes a standoff structure, a first component a second component, and an interposer. The standoff structure defines a space. The first component is disposed within the space. The second component is disposed over the standoff structure. The interposer is disposed between the second component and the standoff structure.

In some arrangements, an electronic device includes a first electronic component, a first carrier, a second carrier, a second electronic component, and a first connector. The first electronic component is disposed over the first carrier. The second carrier is disposed under the first carrier. The second electronic component is disposed over the second carrier and is configured to receive a regulated power from the first electronic component. The first connector is configured to receive a signal from an external device. An elevation of the first connector is between an elevation of the first carrier and an elevation of the second carrier.

In some arrangements, an electronic device includes a first electronic component, a second electronic component, a third electronic component, a first carrier, a second carrier, and a module. The first electronic component is disposed over the first carrier. The second carrier is disposed under the first carrier. The second electronic component is disposed over the second carrier and configured to receive a regulated power from the first electronic component. The third electronic component is disposed over the second carrier. The module covers the third electronic component and is electrically connected between the second carrier and an external device.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an electronic device, in accordance with some arrangements of the present disclosure.

FIG. 2A illustrates a partial enlarged view of the electronic device as shown in FIG. 1, in accordance with some arrangements of the present disclosure.

FIG. 2B illustrates a perspective view of a standoff structure, in accordance with some arrangements of the present disclosure.

FIG. 3 illustrates a cross-sectional view of an electronic device, in accordance with some arrangements of the present disclosure.

FIG. 4 illustrates a cross-sectional view of an electronic device, in accordance with some arrangements of the present disclosure.

FIG. 5 illustrates a cross-sectional view of an electronic device, in accordance with some arrangements of the present disclosure.

FIG. 6 illustrates a cross-sectional view of an electronic device, in accordance with some arrangements of the present disclosure.

FIGS. 7A, 7B, 7C, and 7D illustrate various stages of a method for manufacturing an electronic device in accordance with some embodiments of the present disclosure.

FIGS. 8A, 8B, and 8C illustrate various stages of a method for manufacturing an electronic device in accordance with some embodiments of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

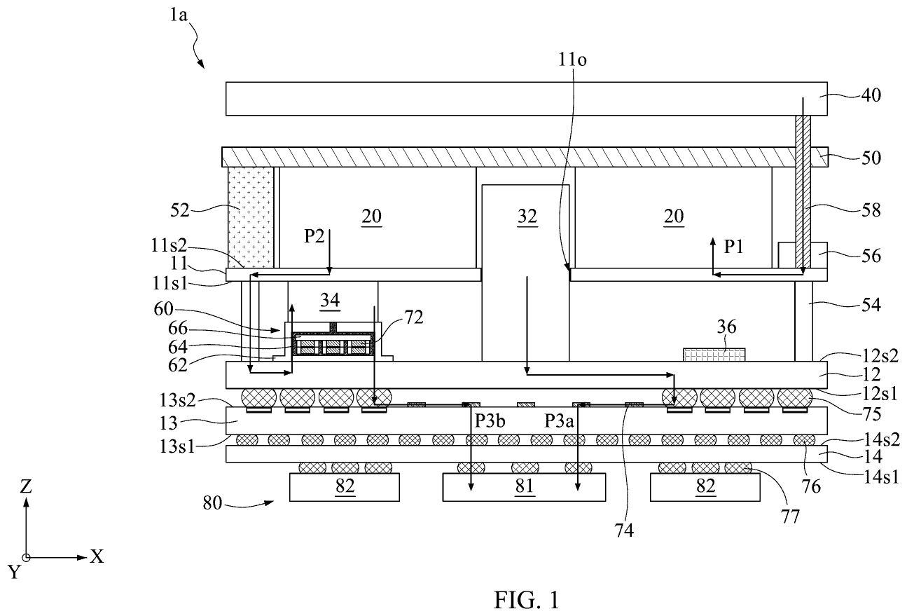

FIG. 1 illustrates an electronic device 1a, in accordance with some arrangements of the present disclosure. In some arrangements, the electronic device 1a may include carriers 11 and 12, electronic components 20, 32, 34, and 36, a circuit structure 40, a heat dissipating structure 50, as well as a system 60.

Each of the carriers 11 and 12 may be formed as a printed circuit board (PCB), flexible printed circuit board (FPCB), lead frame, a combination thereof, or other suitable circuit structures. The carriers 11 and 12 may be at different levels (or elevation or height) along the Z direction. Each of the carriers 11 and 12 may include multiple metal layers separated from one another by layers of dielectric material and interconnected by electrically conductive vias. In some embodiments, each of the carriers 11 and 12 may be formed of an epoxy resin, a fiberglass-reinforced epoxy resin, an epoxy resin with inorganic fillers, a ceramic material, or a polymer material such as polyimide. The carrier 11 may have a surface 11s1 (or lower surface) and a surface 11s2 (or upper surface) opposite to the surface 11s1. The carrier 12 may have a surface 12s1 (or lower surface) and a surface 12s2 (or upper surface) opposite to the surface 12s1. The carrier 11 may be disposed over the surface 12s2 of the carrier 12. In some arrangements, a portion of the surface 12s2 of the carrier 12 may be exposed by the carrier 11.

The electronic component 20 may be disposed on or over the surface 11s2 of the carrier 11. In some arrangements, the electronic component 20 may function as a first stage power module (or first power conversion stage or converter or electrical converter). In some arrangements, the electronic component 20 may be configured to convert a higher voltage (e.g., 48 V) to a lower voltage (e.g., 12 V). For example, the electronic component 20 may be configured to receive a higher voltage from the circuit structure 40 and transmit a lower voltage to the electronic component 32 (or electronic component 34). In some arrangements, the electronic component 20 may include at least one power module (or converter), which includes a transistor(s), a diode(s), a capacitor(s), an inductor(s), and/or other suitable elements. For example, the electronic component 20 may include a circuit structure formed as a PCB, FPCB, or other suitable circuit structures. The active components (e.g., converters, controllers, and/or drivers) and passive components (e.g., capacitors and/or inductors) may be disposed on the circuit structure.

The electronic components 32 and 34 may be disposed on or over the surface 12s2 of the carrier 12. Each of the electronic components 32 and 34 may function as a second stage power module (or second power conversion stage or converter or electrical converter). In some arrangements, each of the electronic components 32 and 34 may be configured to convert a higher voltage (e.g., 12 V) to a lower voltage (e.g., 8 V, 6 V, 4 V, 2 V, or less). In some arrangements, the electronic components 32 and 34 may have different thicknesses along the Z direction. The electronic components 32 and 34 may be electrically connected to the carrier 11. The electronic components 32 and 34 may be electrically connected to the carrier 12. The electronic components 32 and 34 may include multiple elements on a circuit structure (e.g., PCB). For example, the electronic components 32 and 34 may include a transistor(s), a controller(s), and a passive element(s). It should be noted that the electronic device 1a may include more components between the carriers 11 and 12. In some arrangements, each of the electronic components 32 and 34 may also be referred to as a voltage regulator or power block.

In some arrangements, the electronic component 32 may be partially disposed within an opening 11o defined by the carrier 11. In some arrangements, a portion of the electronic component 32 may be protruded from the surface 11s2 of the carrier 11. In some arrangements, the thickness (e.g., the length along the Z direction) of the electronic component 32 may be greater than that of the electronic component 20. The electronic component 34 may be disposed within a space defined by the carriers 11 and 12. In some arrangements, the electronic component 34 may be in contact with the surface 11s1 of the carrier 11. In other arrangements, the electronic component 34 may be spaced apart from the surface 11s1 of the carrier 11. In some arrangements, the electronic component 34 may have a thickness (e.g., the length along the Z direction) less than that of the electronic component 20. In some arrangements, the thickness of the electronic component 32 may be greater than or equal to 7 mm, such as 7 mm, 8 mm, 9 mm, 10 mm, or more. In some arrangements, the thickness of the electronic component 20 may range between 3 mm and 7 mm, such as 3 mm, 4 mm, 5 mm, 6 mm, or 7 mm. The thickness of the electronic component 34 may range between about 1 mm and 5 mm, such as 1 mm, 2 mm, 3 mm, 4 mm, or 5 mm.

In some arrangements, the electronic component 36 may be disposed on or over the surface 12s2 of the carrier 12. In some arrangements, the electronic component 36 may be disposed between the carriers 11 and 12. In some arrangements, the electronic component 36 may function as a second stage power module which is configured to convert a higher voltage (e.g., 12 V) to a lower voltage (e.g., 8 V, 6 V, 4 V, 2 V, or less). In some arrangements, the electronic component 36 may include a controller which is configured to switch the electronic component 32 (or electronic component 34). For example, the electronic component 36 may be configured to turn on or turn off the electronic component 32 (or electronic component 34). In some arrangements, the electronic component 36 may have a dimension (e.g., the thickness along the Z direction) less than that of the electronic component 34.

In some arrangements, the circuit structure 40 (or power delivery board) may be disposed on or over the surface 11s2 of the carrier 11. In some arrangements, the circuit structure 40 may be configured to provide the electronic component 20 with a relatively great power (e.g., 48 V). In some arrangements, the circuit structure 40 may be configured to transmit a signal (e.g., non-power signal or data signal) to the carrier 12. In some arrangements, the circuit structure 40 may include a PCB, FPCB, or other suitable circuit structures. One or more electronic components (not shown) may be disposed on or over the circuit structure 40. For example, the electronic device 1a may include a power management integrated circuit (PMIC) die on or within the circuit structure 40. In this disclosure, the circuit structure 40 may also be referred to as an external device.

In some arrangements, the heat dissipating structure 50 may be disposed between the electronic component 20 and the circuit structure 40. In some arrangements, the heat dissipating structure 50 may be thermally coupled to the electronic component 20. For example, the heat dissipating structure 50 may be configured to transmit heat from the electronic component 20. In some arrangements, the heat dissipating structure 50 may be thermally coupled to the circuit structure 40. For example, the heat dissipating structure 50 may be configured to transmit heat from the circuit structure 40. In some arrangements, the heat dissipating structure 50 may be in contact with the electronic component 20. In some arrangements, the heat dissipating structure 50 may be spaced apart from the electronic component 20 by a thermal interface material (TIM) or adhesive. The heat dissipating structure 50 may include a cold plate, which may include a vapor chamber, heat pipe, and/or other suitable elements. The heat dissipating structure 50 may include thermal conductive materials, such as aluminum (Al), copper (Cu), chromium (Cr), tin (Sn), gold (Au), silver (Ag), nickel (Ni) or stainless steel, or a mixture, an alloy, or other combinations thereof.

In some arrangements, the electronic device 1a may include blocks 52. The blocks 52 may be disposed on or over the surface 11s2 of the carrier 11. In some arrangements, the blocks 52 may function as a spacer configured to adjust a distance between the heat dissipating structure 50 and the carrier 11. In some arrangements, the blocks 52 may be configured to be thermally coupled to the electronic component 20. The blocks 52 may include thermal conductive materials, such as aluminum (Al), copper (Cu), chromium (Cr), tin (Sn), gold (Au), silver (Ag), nickel (Ni) or stainless steel, or a mixture, an alloy, or other combinations thereof.

In some arrangements, the electronic device 1a may include interconnections 54. In some arrangements, the interconnections 54 may be disposed on or over the surface 12s2 of the carrier 12. The interconnections 54 may be disposed at a peripheral region of the carrier 12. For example, the interconnections 54 may surround the electronic components 32 and 34. The interconnections 54 may be disposed between the carriers 11 and 12. In some arrangements, the interconnections 54 may be configured to support the carrier 11. In some arrangements, the interconnections 54 may electrically connect the carriers 11 and 12. In some arrangements, the interconnections 54 may be configured to transmit power and/or signal. In some arrangements, the interconnections 54 may include a pogo pin, conductive pillar, or other suitable conductive elements. In other arrangements, the interconnections 54 may be replaced by an interposer(s), which may include a substrate (e.g., silicon substrate or other substrate) and conductive elements (e.g., through silicon via (TSV)) in the substrate. In other arrangements, the interconnections 54 may be replaced by other conductive components, such as solder materials.

The electronic device 1a may include a connector 56 and conductive elements 58. In some arrangements, the connector 56 may be disposed on or over the surface 11s2 of the carrier 11. In some arrangements, the connector 56 may be configured to connect, hold, or accommodate the conductive elements 58. For example, the connector 56 may define a recess for accommodating a portion of the conductive elements 58. In some arrangements, the conductive elements 58 may be connected between the carrier 11 and the circuit structure 40. The conductive elements 58 may be disposed on or over the surface 11s2 of the carrier 11. In some arrangements, the conductive elements 58 may be configured to transmit power (or power signal) between the electronic component 20 and circuit structure 40. For example, the conductive elements 58 may be configured to transmit a relatively great power (e.g., 48 V) from the circuit structure 40 to the electronic component 20. In some arrangements, the conductive elements 58 may penetrate the heat dissipating structure 50. In some arrangements, the conductive elements 58 may include a pogo pin, conductive pillar, or other suitable conductive elements. The circuit structure 40 may be configured to provide the electrical path (or power path) conducting power P1 (e.g., 48V) to the electronic component 20 through the conductive elements 58 and carrier 11. In some arrangements, the carriers 11 and 12 and interconnections 54 may be configured to provide the electrical path (or power path) conducting power P2 (e.g., 12 V) from the electronic component 20 to the electronic component 34. Similarly, the electronic component 32 may be configured to receive the power (e.g., 12 V) through the carriers 11 and 12 and interconnections 54 from the electronic component 20.

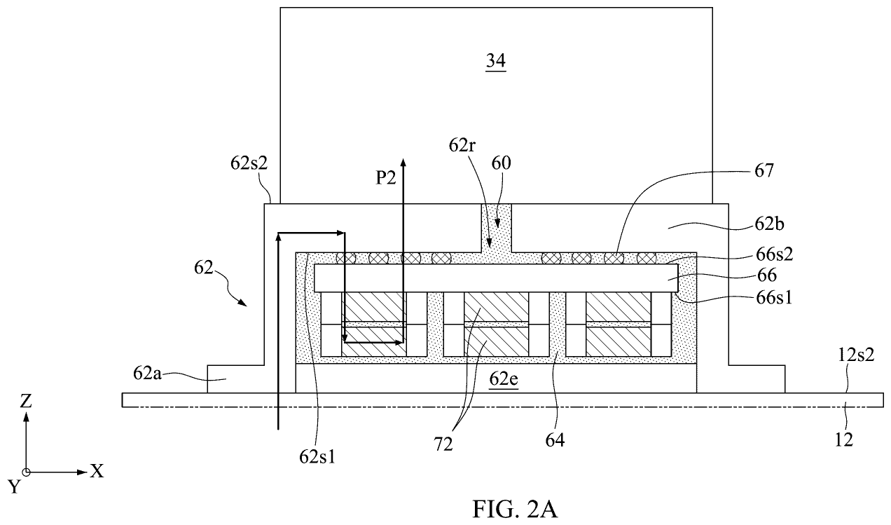

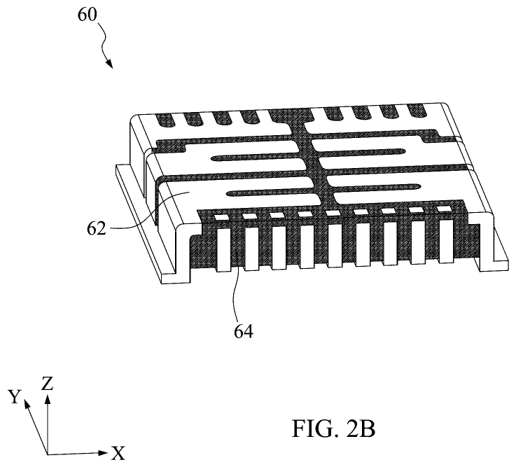

In some arrangements, the system 60 may be disposed on or over the surface 12s2 of the carrier 12. In some arrangements, the system 60 may support the electronic component 34. The system 60 may vertically overlap the electronic component 34. In some arrangements, the system 60 may include a system-in-package (SiP). In some arrangements, the system 60 may be configured to regulate the power from or toward the electronic component 20, 32, and/or 34. Please refer to FIGS. 2A and 2B, the system 60 may include an interposer 66 and passive devices 72.

In some arrangements, the electronic device 1a may include a conductive structure 62. The conductive structure 62 may be disposed over and attached to the surface 12s2 of the carrier 12. The conductive structure 62 may define a conductive pattern electrically connected to the electronic component 34 and the interposer 66. The conductive structure 62 may be electrically connected between the system 60 and the electronic component 34. In some arrangements, the conductive structure 62 may function as a spacer or a standoff structure and be configured to separate the electronic component 34 from the carrier 12. The conductive structure 62 may have supporting portions 62a and a plate 62b supported by the supporting portions 62a. The conductive structure 62 may have a surface 62s1 and a surface 62s2 on the two opposite sides of the plate 62b. In some arrangements, the electronic component 34 may be disposed over the surface 62s2 of the conductive structure 62. In some arrangements, the conductive structure 62 may include a conductive material, such as copper (Cu), aluminum (Al), chromium (Cr), tin (Sn), gold (Au), silver (Ag), nickel (Ni) or stainless steel, or a mixture, an alloy, or other combinations thereof. In some arrangements, the conductive structure 62 may be configured to define a space 62e extending between the surface 62s1 of the conductive structure 62 and the surface 12s2 of the carrier 12. The system 60 may be spaced apart from the carrier 12 by the conductive structure 62. The conductive structure 62 may define a recess 62r extending between the surfaces 62s1 and 62s2. The electronic component 34 may overlap the recess 62r along the Z direction.

In some arrangements, the electronic device 1a may include an encapsulant 64. The encapsulant 64 may encapsulate the system 60. The encapsulant 64 may partially encapsulate the conductive structure 62, and a portion of the conductive structure 62 may be exposed by the upper surface and the lateral surface of the encapsulant 64. In some arrangements, the encapsulant 64 may occupy a portion of the space 62e. In some arrangements, the encapsulant 64 may include a molding compound. In some arrangements, the encapsulant 64 may be spaced apart from the surface 12s2 of the carrier 12. The encapsulant 64 may include a novolac-based resin, an epoxy-based resin, a silicone-based resin, or another suitable material. Suitable fillers may also be included, such as powdered SiO₂. The encapsulant 64 may be applied using any of a number of molding techniques, such as compression molding, injection molding, selective molding, or transfer molding. In other embodiments, the encapsulant 64 may include, for example, organic materials (e.g., a bismaleimide triazine (BT), a polyimide (PI), a polybenzoxazole (PBO), a solder resist, an ABF, a polypropylene (PP) or an epoxy-based material), inorganic materials (e.g., a silicon, a glass, a ceramic or a quartz), liquid and/or dry-film materials or a combination thereof. In some arrangements, the encapsulant 64 and the conductive structure 62 may collectively be referred to as a lead frame. In some arrangements, the conductive structure 62 and the encapsulant 64 may be included in the system 60. The encapsulant 64 may be exposed by the recess 62r.

In some arrangements, the interposer 66 (or circuit structure) may be disposed under the surface 62s1 of the conductive structure 62. In some arrangements, the interposer 66 may be embedded within or encapsulated by the encapsulant 64. The interposer 66 may be electrically connected to the electronic component 34. The interposer 66 may be spaced apart from the electronic component 34 by the conductive structure 62 and the encapsulant 64. The interposer 66 may be electrically connected to the conductive structure 62 by electrical connectors 67. In some arrangements, the electrical connectors 67 may be or include electrical contacts, such as solder balls (e.g., controlled collapse chip connection (C4) bumps, a ball grid array (BGA), a land grid array (LGA)), conductive bumps, or the like. In other arrangements, the interposer 66 may be electrically connected to the conductive structure 62 by, for example, conductive wires (or bonding wires). In some arrangements, the interposer 66 may include a PCB, FPCB, or other suitable circuit structures. The interposer 66 may have a surface 66s1 (or lower surface) facing the carrier 12 and a surface 66s2 (or upper surface) facing the conductive structure 62. The interposer 66 may overlap the recess 62r along the Z direction.

In some arrangements, the passive devices 72 may be disposed over the surface 12s2 of the carrier 12. In some arrangements, the passive devices 72 may be attached to or mounted on the surface 66s1 of the interposer 66. The passive devices 72 may be electrically connected to the electronic component 34 through the conductive structure 62 and the interposer 66. In some arrangements, the passive devices 72 may be embedded within or encapsulated by the encapsulant 64. In some arrangements, the passive devices 72 may be spaced apart from the carrier 12. The passive devices 72 may include input capacitors (Cin) through which the power flows before being delivered to the electronic component 32 (or electronic component 34). For example, the electrical path conducting the power P2 (or other power from another power source or regulator) may be transmitted from the carrier 12 to the electronic component 34 through the conductive structure 62, the interposer 66, the passive devices 72, the interposer 66, and the conductive structure 62. In some arrangements, two or more passive devices 72 may be stacked on each other. In some arrangements, two or more passive devices 72 may vertically overlap each other.

Please refer back to FIG. 1, the electronic device 1a may include a carrier 13. In some arrangements, the carrier 13 may be formed as a printed circuit board, flexible printed circuit board, or other suitable circuit structures. The carrier 13 may include multiple metal layers separated from one another by layers of dielectric material and interconnected by electrically conductive vias. In some embodiments, the carrier 13 may be formed of an epoxy resin, a fiberglass-reinforced epoxy resin, an epoxy resin with inorganic fillers, a ceramic material, or a polymer material such as polyimide. The carrier 13 may have a surface 13s1 (or lower surface) and a surface 13s2 (or upper surface) opposite to the surface 13s1. The surface 13s2 of the carrier 13 may face the surface 12s1 of the carrier 12.

In some arrangements, the electronic device 1a may include passive devices 74. The passive devices 74 may be disposed under the surface 12s1 of the carrier 12. The passive devices 74 may be disposed over or mounted on the surface 13s2 of the carrier 13. In some arrangements, the passive devices 74 may be disposed between the carriers 12 and 13. The passive devices 74 may be electrically connected to the carrier 13. In some arrangements, the passive devices 74 may be configured to regulate the power from the electronic component 32 (or electronic component 34) toward an operating module 80 (or computing module). In some arrangements, the passive devices 74 may include output capacitors (Cout) through which the power flows after being transmitted from the electronic component 32 (or electronic component 34).

In some arrangements, the passive device 72 may have a capacitance greater than that of the passive device 74. In some arrangements, the passive device 72 may have a dimension (e.g., volume or thickness) greater than that of the passive device 74. In some arrangements, the number of the passive devices 74 may be greater than that of the passive devices 72. In some arrangements, the passive devices 72 and passive devices 74 are disposed at different levels along the Z direction. In some arrangements, a vertical distance between the passive devices 72 and the electronic component 34 may be less than a vertical distance between the passive devices 74 and the electronic component 34 along the Z direction. In some arrangements, the electrical path between the passive devices 72 and the electronic component 34 (or electronic component 32) may be less than the electrical path between the passive devices 74 and the electronic component 34 (or electronic component 32). Since the current flowing into passive device 72 is greater than that entering passive device 74, a shorter electrical path between passive device 72 and electronic component 34 (or electronic component 32) may help minimize power loss.

The electronic device 1a may include electrical connectors 75. The electrical connectors 75 may be disposed between the carriers 12 and 13. The electrical connectors 75 may be or include electrical contacts, such as solder balls (e.g., controlled collapse chip connection (C4) bumps, a ball grid array (BGA), a land grid array (LGA)), conductive bumps, or the like. The electrical connectors 75 may include alloys of gold and tin solder or alloys of silver and tin solder, or other suitable materials.

The electronic device 1a may include a carrier 14 (or substrate). In some arrangements, the carrier 14 may be disposed on or under the surface 13s1 of the carrier 13. In some arrangements, the carrier 14 may include a semiconductor substrate, such as silicon, germanium, and other group III-V and group IV materials. The carrier 14 may include metal lines and vias, including but not limited to through-silicon vias (TSVs) for interconnection. In some arrangements, the carrier 14 may include a wafer form, a panel form or other suitable forms. The carrier 14 may have a surface 14s1 (or a lower surface) and a surface 14s2 (or an upper surface) opposite to the surface 14s1.

The carrier 14 may be electrically connected to the carrier 13 through electrical connectors 76. The carrier 14 may be configured to support the operating module 80. In some arrangements, the electrical connectors 76 may include a reflowable material. The electrical connectors 76 may be or include electrical contacts, such as solder balls (e.g., controlled collapse chip connection (C4) bumps, a ball grid array (BGA), a land grid array (LGA)), conductive bumps, or the like. The electrical connectors 76 may include alloys of gold and tin solder or alloys of silver and tin solder, or other suitable materials.

In some arrangements, the operating module 80 may be disposed on or under the surface 14s1 of the carrier 14. In some arrangements, the operating module 80 may be configured to generate non-power signals, such as analog signals, digital signals, clock signals, or other electrical signals. The operating module 80 may include electronic components 81 and 82. In some arrangements, the electronic components 81 and 82 may be disposed on or under the surface 14s1 of the carrier 14. In some arrangements, the electronic component 81 may include a processor or other suitable components. In some arrangements, the electronic component 81 may include an active device, such as a central processing unit (CPU), a microprocessor unit (MPU), a graphics processing unit (GPU), a microcontroller unit (MCU), a radio frequency integrated circuit (RFIC), an application-specific IC (ASIC), a field-programmable gate array (FPGA), or another type of IC. In some arrangements, the electronic component 82 may include a data storage unit or other suitable components. The electronic component 82 may be electrically connected to the electronic component 81 through the carrier 14. The electronic component 82 may be disposed on or under the surface 14s1 of the carrier 14. In some arrangements, the electronic component 82 may be configured to store the signals from the electronic component 81 and/or other devices. In some arrangements, the electronic component 82 may include a high band memory (HBM) die, dynamic random access memory (DRAM) die, static random access memory (SRAM) die, or other suitable memory devices. In some arrangements, the operating module 80 may further include other components, such as input/output dies configured to receive regulated power from the electronic component 32 (or electronic component 34) and/or transmit a processed signal to other devices (not shown). The electronic components 81 and 82 may be electrically connected to the carrier 14 by electrical connectors 77. In some arrangements, the electrical connectors 77 may include a reflowable material. The electrical connectors 77 may be or include electrical contacts, such as solder balls (e.g., controlled collapse chip connection (C4) bumps, a ball grid array (BGA), a land grid array (LGA)), conductive bumps, or the like. The electrical connectors 77 may include alloys of gold and tin solder or alloys of silver and tin solder, or other suitable materials. In other arrangements, the electronic components 81 and 82 may be electrically connected to the carrier 14 by hybrid-bond techniques, which involve a bonding between metallic materials (e.g., a bonding between copper and copper) and a bonding between dielectric materials (e.g., a bonding between oxide and oxide).

The operating module 80 may be configured to receive powers P3a and P3b (or regulated powers) from the electronic components 32 and 34, respectively. In some arrangements, the carrier 12 may be configured to provide the electrical path (or power path) conducting the powers P3a and P3b. In some arrangements, the system 60 may be configured to provide the electrical path (or power path) conducting the power P3b. In some arrangements, the carrier 13 may be configured to provide the electrical path (or power path) conducting the powers P3a and P3b. In some arrangements, the carrier 14 may be configured to provide the electrical path (or power path) conducting the powers P3a and P3b. In some arrangements, the electronic components 32 and 34 may provide the operating module 80 with powers at different levels (e.g., 8 V, 6 V, 4 V, 2 V, or less). For example, the power P3a may be different from the power P3b.

In a comparative example, input capacitors and output capacitors are disposed on or mounted on the same carrier. However, as the demand for computational speed increases, more capacitors, especially output capacitors, are needed. In this condition, the comparative example necessitates a carrier with a larger surface area, which negatively impacts the miniaturization of the electronic device. In this configuration, some passive devices (e.g., passive devices 72) are placed on the conductive structure 62, potentially enabling the accommodation of additional passive devices 74 on the carrier 13. Moreover, the passive devices 72 can be stacked to achieve a higher capacitance per unit area, thereby improving the performance of the electronic device 1a.

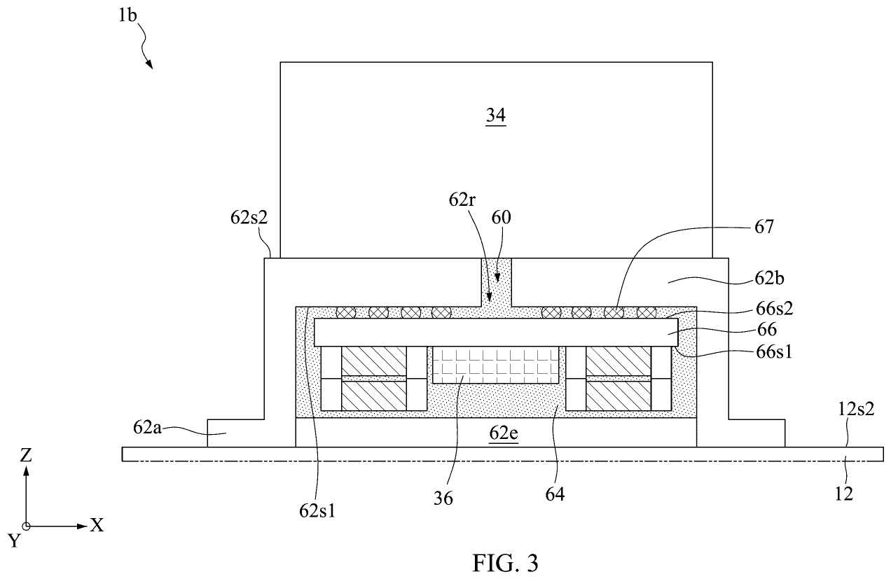

FIG. 3 illustrates a cross-sectional view of an electronic device 1b, in accordance with some arrangements of the present disclosure. The electronic device 1b is similar to the electronic device 1a, differing as follows.

In some arrangements, the electronic component 36 may be integrated within the system 60. In some arrangements, the electronic component 36 may be disposed on or under the surface 62s1 of the conductive structure 62. In some arrangements, the electronic component 36 may be disposed on or under the surface 66s1 of the interposer 66. In some arrangements, the electronic component 36 may be embedded within or encapsulated by the encapsulant 64. In some arrangements, the electronic component 36 may be electrically connected to the electronic component 34 through the conductive structure 62 and the interposer 66. In some arrangements, the electronic component 36 may be spaced apart from the carrier 12. The electronic component 36 may laterally overlap the passive devices 72 or overlap the passive devices 72 along the XY plane. In some arrangements, the electronic component 36 and the passive devices 72 may be arranged side by side. In some arrangements, the electronic component 36 and the passive devices 72 may be attached to or mounted on the surface 66s1 of the interposer 66. In some arrangements, the electronic component 36 and the passive devices 72 may be supported by the surface 66s1 of the interposer 66. In this arrangement, the electronic component 36 may be disposed within the space 62e without occupying additional areas, thereby reducing the surface area (e.g., the surface area along the XY plane) of the carrier 12. The electronic component 36 may overlap the recess 62r along the Z direction.

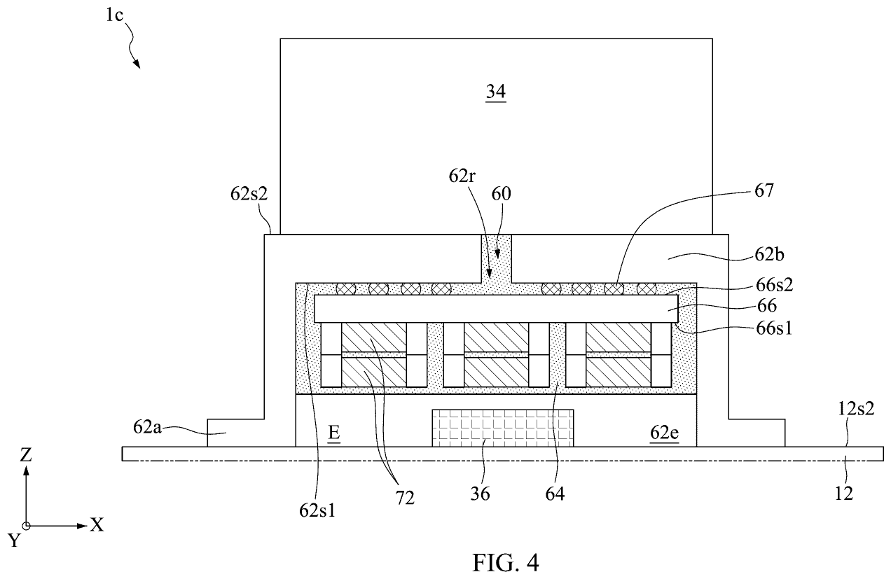

FIG. 4 illustrates a cross-sectional view of an electronic device 1c, in accordance with some arrangements of the present disclosure. The electronic device 1c is similar to the electronic device 1a, differing as follows.

In some arrangements, the electronic component 36 may be mounted on the carrier 12 and disposed within the space 62e. In some arrangements, the electronic component 36 may be disposed within the space E defined by the encapsulant 64, the conductive structure 62, and the carrier 12. The electronic component 36 may vertically overlap the system 60. In some arrangements, the electronic component 36 may vertically overlap the passive devices 72. The electronic component 36 may vertically overlap the encapsulant 64. In some arrangements, the electronic component 36 may be spaced apart from the encapsulant 64. In some arrangements, the electronic component 36 may be electrically connected to the electronic component 34 through the conductive structure 62. In this arrangement, the electronic component 36 may be disposed within the space 62e without occupying additional areas, thereby reducing the surface area (e.g., the surface area along the XY plane) of the carrier 12.

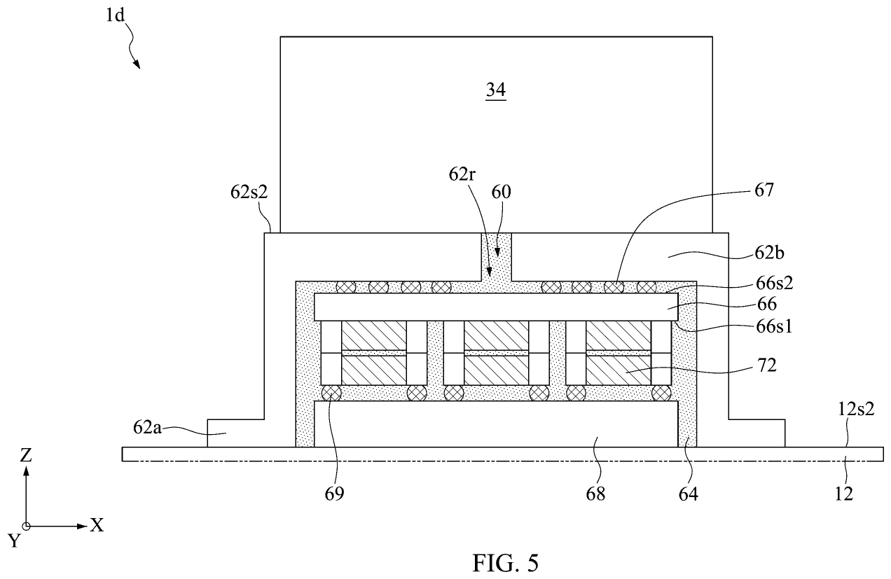

FIG. 5 illustrates a cross-sectional view of an electronic device 1d, in accordance with some arrangements of the present disclosure. The electronic device 1d is similar to the electronic device 1a, differing as follows.

In some arrangements, the system 60 may include an interposer 68. The interposer 68 may be disposed within the space 62e. In some arrangements, the interposer 68 may be electrically connected to the passive devices 72. In some arrangements, the interposer 68 may be electrically connected between the carrier 12 and the passive devices 72. The interposer 68 may be electrically connected to the passive devices 72 through electrical connectors 69. The electrical connectors 69 may include alloys of gold and tin solder or alloys of silver and tin solder, or other suitable materials. The interposer 68 may include a PCB, FPCB, or other suitable circuit structures. In some arrangements, the interposer 68 may include a silicon interposer which contains through-silicon-via (TSV). In this arrangement, power (e.g., the power P2 shown in FIG. 2A) may be transmitted to the passive devices 72 through the interposer 68 without passing through the conductive structure 62. The interposer 68 may be electrically connected to the carrier 12 by solder balls, pads, conductive wires, or other suitable elements.

In some arrangements, the lower surface of the interposer 68 may be substantially aligned with the lower surface of the encapsulant 64. In some arrangements, the encapsulant 64 may be in contact with the surface 12s2 of the carrier 12. In this arrangement, the interposer 68 serves as a protective structure designed to prevent the passive devices 72 from being ground during the polishing process applied to the encapsulant 64.

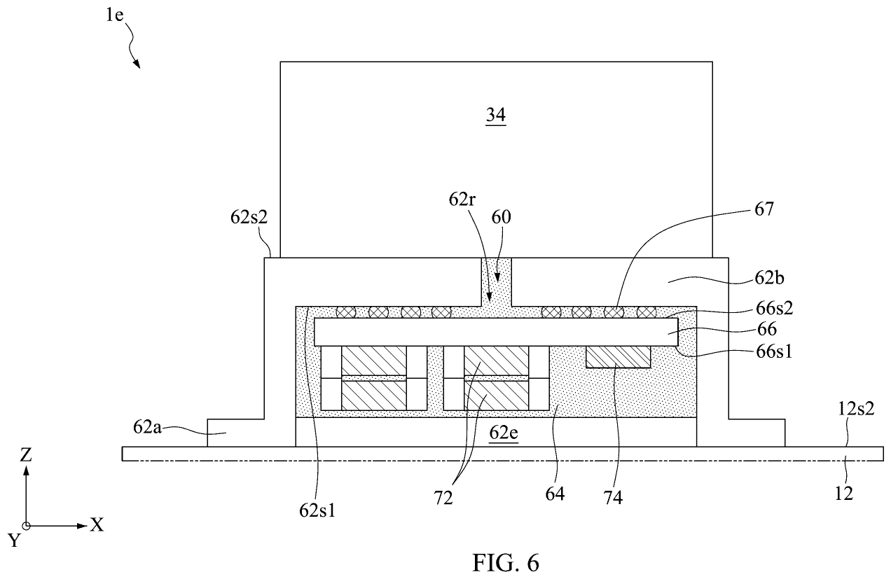

FIG. 6 illustrates a cross-sectional view of an electronic device 1e, in accordance with some arrangements of the present disclosure. The electronic device 1e is similar to the electronic device 1a, differing as follows.

In some arrangements, a portion of the passive devices 74 may be disposed within the space 62e. In some arrangements, the passive devices 72 and passive devices 74 may be arranged side by side. In some arrangements, the passive devices 72 and passive devices 74 may be attached to or mounted on the surface 66s1 of the interposer 66. In some arrangements, the passive devices 72 and passive devices 74 may be supported by the surface 66s1 of the interposer 66. In some arrangements, the passive devices 74 may be electrically connected to the electronic component 34 through the conductive structure 62 and the interposer 66. In some arrangements, the passive devices 74 may be encapsulated by the encapsulant 64. In this arrangement, a portion of the passive devices 74 may be disposed within the space 62e, potentially enabling the accommodation of additional passive devices 74 on the carrier 13.

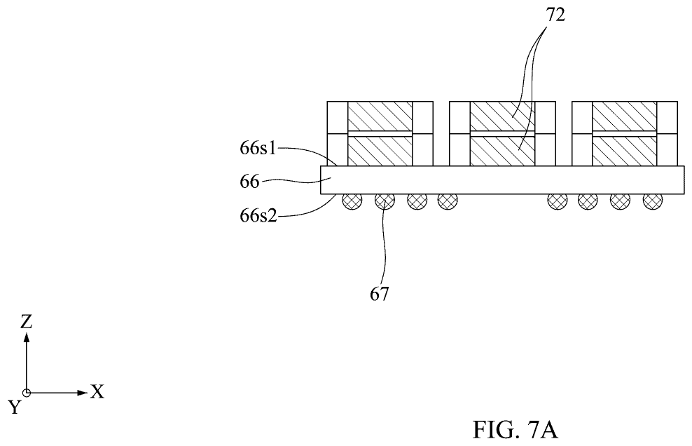

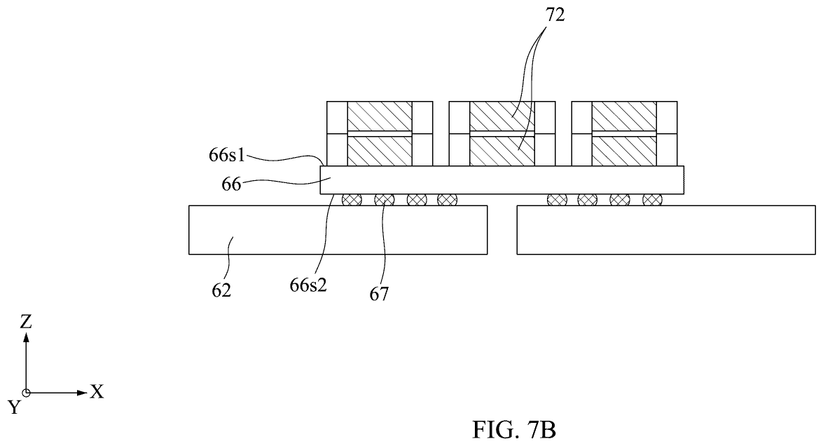

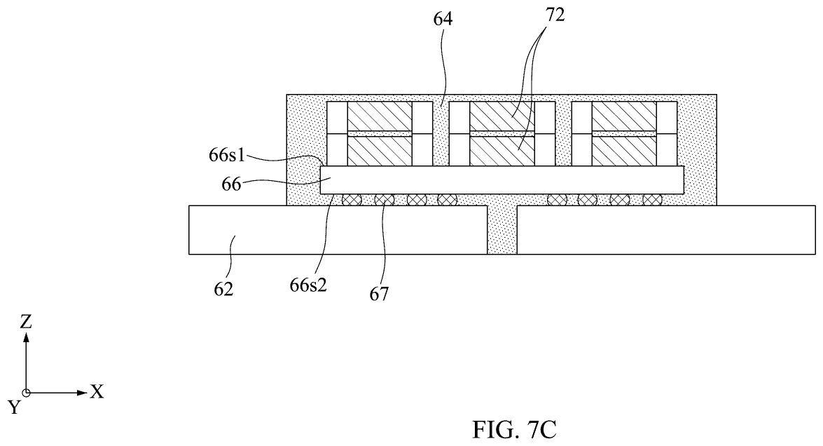

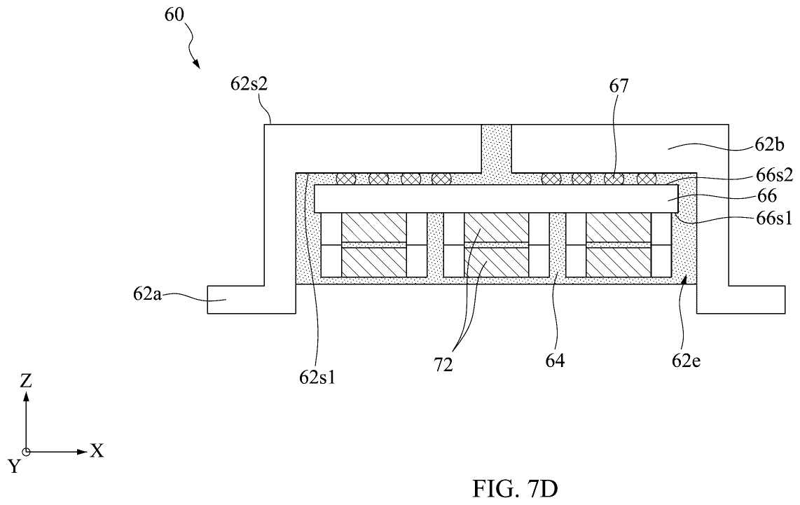

FIGS. 7A, 7B, 7C, and 7D illustrate various stages of a method for manufacturing a system (e.g., SiP) in accordance with some embodiments of the present disclosure.

Referring to FIG. 7A, the interposer 66 may be provided. The passive devices 72 may be mounted on the interposer 66. In some arrangements, two or more passive devices 72 may be stacked on each other.

Referring to FIG. 7B, the interposer 66 may be mounted on the conductive structure 62 through the electrical connectors 67.

Referring to FIG. 7C, the encapsulant 64 may be formed on the conductive structure 62 to encapsulate the interposer 66 and the passive devices 72. In some arrangements, a polishing technique or grinding technique may be performed on the encapsulant 64.

Referring to FIG. 7D, the conductive structure 62 may be deformed to define the supporting portions 62a and the plate 62b. The space 62e may be defined. As a result, a system (e.g., the system 60) as shown in FIG. 2A may be produced.

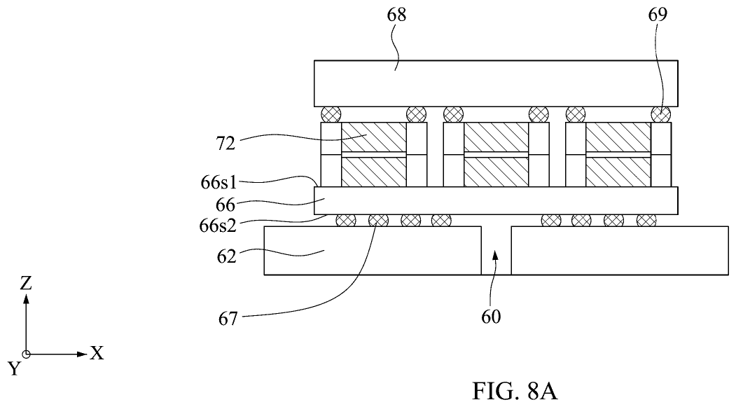

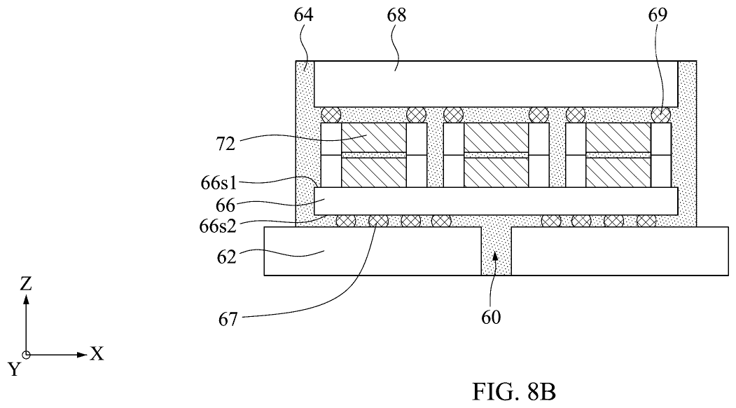

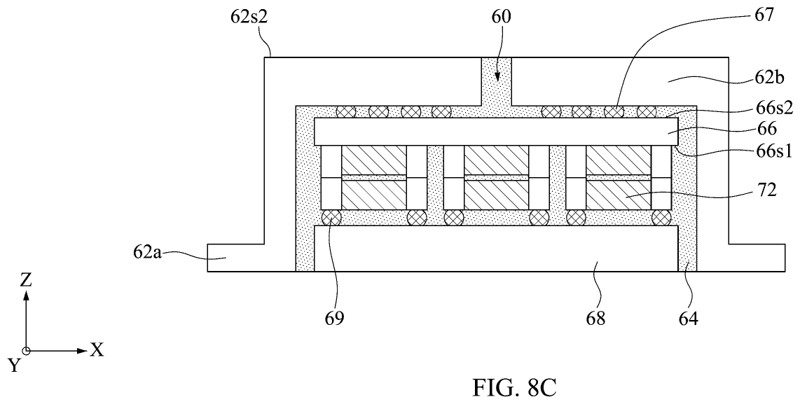

FIGS. 8A, 8B, and 8C illustrate various stages of a method for manufacturing a system (e.g., SiP) in accordance with some embodiments of the present disclosure.

Referring to FIG. 8A, the interposer 68 may be stacked on the passive devices 72 by soldering the passive devices 72 and the electrical connectors 69.

Referring to FIG. 8B, the encapsulant 64 may be formed on the conductive structure 62 to encapsulate the interposers 66 and 68 as well as the passive devices 72. In some arrangements, a polishing technique or grinding technique may be performed on the encapsulant 64, and the terminals of the interposer 68 may be exposed by the encapsulant 64. In this arrangement, the interposer 68 serves as a protective structure designed to prevent the passive devices 72 from being ground during the polishing technique or grinding technique.

Referring to FIG. 8C, the conductive structure 62 may be deformed to define the supporting portions 62a and the plate 62b. As a result, a system (e.g., the system 60) as shown in FIG. 5 may be produced.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first carrier having a first surface and a second surface opposite to the first surface;
a converter disposed over the second surface of the first carrier;
an input capacitor electrically connected to the converter and disposed over the second surface of the first carrier; and
an output capacitor electrically connected to the converter and disposed under the first surface of the first carrier.

2. The electronic device of claim 1, further comprising:
a standoff structure disposed over the second surface of the first carrier,
wherein the standoff structure vertically overlaps the input capacitor.

3. The electronic device of claim 2, wherein the standoff structure is disposed between the converter and the input capacitor.

4. The electronic device of claim 2, further comprising:
a circuit structure between the standoff structure and the input capacitor.

5. The electronic device of claim 4, wherein the standoff structure has a first surface facing the first carrier and a second surface opposite to the first surface, the converter is attached to the second surface of the standoff structure, and the circuit structure is attached to the first surface of the standoff structure.

6. The electronic device of claim 2, further comprising:
an encapsulant encapsulating the standoff structure.

7. The electronic device of claim 6, wherein the input capacitor is encapsulated by the encapsulant.

8. The electronic device of claim 6, wherein the encapsulant is spaced apart from the first carrier.

9. The electronic device of claim 2, further comprising:
an electronic component attached to the standoff structure and laterally overlapping the input capacitor.

10. An electronic device, comprising:
a carrier;
a standoff structure disposed over the carrier;
a converter spaced apart from the carrier by the standoff structure; and
a system-in-package (SiP) electrically connected to the converter by the standoff structure.

11. The electronic device of claim 10, wherein the SiP comprises a first passive device electrically connected to the converter.

12. The electronic device of claim 11, wherein the SiP comprises a circuit structure electrically connected between the first passive device and the standoff structure.

13. The electronic device of claim 11, further comprising:
a second passive device disposed under the carrier and electrically connected to the converter.

14. The electronic device of claim 10, wherein the SiP is disposed within a space defined by the standoff structure.

15. The electronic device of claim 10, further comprising:
a controller disposed between the standoff structure and the carrier, wherein the controller vertically overlaps the SiP.

16. An electronic device, comprising:
a first carrier;
a standoff structure disposed over the first carrier, wherein the first carrier and the standoff structure define a space;
a first converter disposed over the first carrier; and
a first passive device electrically connected to the first converter and disposed within the space.

17. The electronic device of claim 16, further comprising:
a second carrier disposed over the first carrier; and
a second converter disposed over the second carrier and configured to receive a power and generate a regulated power transmitted to the first converter,
wherein the first converter is disposed between the standoff structure and the second carrier.

18. The electronic device of claim 16, further comprising:
an electronic component configured to turn on or turn off the first converter and disposed within the space.

19. The electronic device of claim 18, wherein the electronic component is spaced apart from the first carrier.

20. The electronic device of claim 16, further comprising:
an interposer disposed within the space and electrically connected between the first carrier and the first passive device.
